(19) United States
(12) Patent Application Publication
(10) Pub. No.: US 2025/0115472 A1
(43) Pub. Date: Apr. 10, 2025

(54) MEMS ACCELEROMETER WITH HORIZONTAL SENSE FINGERS

(71) Applicant: ROHM CO., LTD., Kyoto (JP)

(72) Inventors: Andrew Scott HOCKING, Ithaca, NY (US); Martin Wilfried HELLER, Kyoto (JP); Daisuke NISHINOHARA, Kyoto (JP)

(73) Assignee: ROHM CO., LTD., Kyoto (JP)

(21) Appl. No.: 18/622,089

(22) Filed: Mar. 29, 2024

Related U.S. Application Data
(60) Provisional application No. 63/588,639, filed on Oct. 6, 2023.

(51) Int. Cl. B81B 3/00

(52) U.S. Cl. CPC B81B 3/001; B81B 2201/0235; B81B 2203/0136; B81B 2203/0154; B81B 2203/0163; B81B 2203/04; B81B 2203/053

(57) ABSTRACT

A micro-electromechanical systems (MEMS) Z-axis accelerometer can comprise a substrate, a sensor configured to measure an acceleration along an axis that extends in a direction perpendicular to a plane of the substrate, and a spring axis configured to deform axially in response to the acceleration. The sensor can include a comb finger arrangement in which a comb finger overlap area is parallel with the spring axis. Fingers of the comb finger arrangement can extend in a non-sensing direction of lowest restoring force.

### CROSS-REFERENCE TO RELATED APPLICATION

This application claims the benefit of the earlier filing date of provisional application No. 63/588,639, filed Oct. 6, 2023.

### BACKGROUND

### Field of the Invention

The present disclosure relates to accelerometers, and more particularly to micro-electromechanical systems (MEMS) accelerometers.

### Background Discussion

Accelerometers measure forces that may correspond to acceleration. MEMS accelerometers can employ silicon semiconductor technology. A typical MEMS accelerometer can include a proof-mass, restoring springs, a displacement transducer, damping, and a case.

Related art drawings FIGS. 2A and 2B included in this disclosure show basic structures of an accelerometer to illustrate conceptually how accelerometers, including MEMS accelerometers, function. FIG. 2A corresponds to FIG. 1A of U.S. Pat. No. 7,430,909, which is fully incorporated herein by reference. As shown in FIG. 2A, an accelerometer can include a proof mass 1, restoring springs 2, a case 3, displacement transducers 4 and 5, and a damper 6. Displacement transducers 4 and 5 are shown as differential capacitance transducers, but could be piezoelectric transducers or some other form of transducer.

In response to a horizontal acceleration to the left, proof mass 1 will move to the right. As a result of this motion, the capacitance of displacement transducer 5 increases while the capacitance of displacement transducer 4 decreases. The difference in capacitance between displacement transducers 4 and 5 provides a measure of the relative motion of proof mass 1 with respect to case 3, and hence a measure of the acceleration to which proof mass 1 is being subjected. Damper 6 can damp ringing of the accelerometer due to sudden acceleration changes. The proof mass 1 in an actual implementation is not necessarily concentrated in a single point but is distributed. The proof mass consists of anything connected together, having a mass that can be moved by an applied acceleration. Therefore, the springs and parts of the capacitive transducer structure also contribute to the proof mass. Depending on the design, their contribution to the proof mass will vary.

A MEMS accelerometer package can include an Application Specific Integrated Circuit (ASIC). The MEMS accelerometer can be wire bonded to the ASIC. Related art drawing FIG. 2B included with this disclosure illustrates an electrical model for the accelerometer of FIG. 2A. FIG. 2B corresponds to FIG. 1B of U.S. Pat. No. 7,430,909. Referring to FIG. 2B, the differential capacitance between capacitors 4 and 5 can be measured, for example, by square wave carrier signals that are 180 degrees out of phase, and provided to terminals 7 and 8. The magnitude of the square waves depends on the ASIC technology used; however, voltages in the 1.8 to 5V range are typical. By measuring the amount of charge that flows through terminal 9, a capacitance difference can be determined, therefore the acceleration being applied to the accelerometer can be determined.

An accelerometer based on MEMS is typically constructed of three components: (1) a MEMS element that senses acceleration, (2) electronics included in an ASIC that transduces the MEMS element's response to acceleration into an electronic signal, and (3) a package that houses the first and second components.

Related art drawings FIGS. 3A and 3B included in this disclosure show an example of a specific configuration of an accelerometer. FIGS. 3A and 3B correspond to FIGS. 5A and 5B, respectively, of U.S. Pat. No. 7,430,909. FIGS. 3A and 3B show one example of a configuration of a “Z accelerometer” or “Z-axis accelerometer.” A Z-axis accelerometer can measure forces, such as acceleration, acting in a “Z direction,” typically referring to a direction perpendicular or orthogonal to a plane of a substrate on which elements of the accelerometer are formed.

In FIGS. 3A and 3B, the Z direction corresponds to the direction shown by arrow 50. A proof mass 51 is connected to a support structure 55 via flexure 56. Opposing electrodes 52 are supported by support structure 58.

Also shown in FIG. 3B is an area of overlap 53 between the area of proof mass 51 and the area of the opposing electrodes 52. Proof mass 51 is elevated along the direction 50 with respect to opposing electrodes 52. In response to an upward acceleration in the direction of arrow 50, proof mass 51 deflects downwardly towards a substrate 54. Consequently, area of overlap 53 increases. As area of overlap 53 increases so does the capacitance between proof mass 51 and electrodes 52, thereby forming a displacement transducer used in the sensing of acceleration.

Related art drawing FIG. 4 included in this disclosure shows an example of a configuration of a Z axis accelerometer in more detail. FIG. 4 corresponds to FIG. 10A (the left half) of U.S. Pat. No. 7,430,909. In FIG. 4, Z-axis sensor 306 is configured to measure an acceleration along Z-axis 100, i.e., along an axis perpendicular to a plane of a case 310. Z-axis sensor 306 includes a first beam structure 301, a second beam structure 311 and a single support structure 303. Single support structure 303 supports first beam structure 301 and second beam structure 311 relative to case 310.

First beam structure 301 includes a plurality of electrodes 305 and second beam structure 311 includes a plurality of electrodes 315. Electrodes 315 are interdigitated with and electrically coupled to electrodes 305. The electrodes 305 and 315, absent unwanted phenomena as described in more detail further on, are separated by spaces 307. First beam structure 301 moves in the Z direction, that is, into or out of the plane of the drawing, relative to second beam structure 311 in response to an acceleration along Z-axis 100. This causes a measurable change in the electrical coupling between electrodes 305 and 315, due to a change in overlapping area between the electrodes 305 and 315, similarly to the phenomenon described above in connection with related art FIGS. 3A and 3B. While not visible in the view of FIG. 4, it should be understood that electrodes 305 and 315 can be flat, fin-like or plate-like structures, like 51 and 52 in FIGS. 3A and 3B, and thus have overlapping areas like 53 in FIGS. 3A and 3B. Electrodes such as 305 and 315 may be known in the art as “fingers” or “sense fingers.”

Z-axis sensor 306 includes a proof mass 301 that moves up and down, that is, into or out of the plane of the drawing, in the Z direction 100 through a torsional motion about an axis defined by a torsional flexure 302. An effective proof mass can include proof mass 301 along with the moving sense finger portion 305. Together the proof mass 301 and the moving sense finger portion 305 can function as an effective proof mass which moves due to an acceleration.

Flexure 302 connects proof mass 301 to the substrate at support structure 303. A structure such as flexure 302 may also be known in the art as a “spring axis” or “torsion beam.”

There are problems associated with a configuration such as shown in FIG. 4, as will be better understood by reference to related art FIGS. 5A and 5B included in this disclosure. FIGS. 5A and 5B represent a simplified version 306.1 of the Z-axis accelerometer of FIG. 4. The accelerometer 306.1 includes a first, inner beam structure 301.1 and a second, outer beam structure or frame 311.1, electrodes 305.1 and 315.1 electrically coupled to each other, support 303.1 and a torsion beam 302.1. Electrodes 305.1 and 315.1 are separated by spaces 307.1. In response to a force, such as acceleration, in the Z direction, the inner beam structure 301.1, acting as part of an effective proof mass, moves in and out of the plane of the drawing in the Z direction, causing a measurable change in the electrical coupling between electrodes 305.1 and 315.1.

However, along with a force in the Z direction there may be forces in the X and Y directions as well, which can lead to the situation shown in FIG. 5B. In FIG. 5B, the inner beam structure 301.1 has tilted or wobbled in the X and Y directions, causing the spaces 307.1 to be closed and the electrodes 305.1 and 315.1 to come into contact with each other. This unwanted phenomenon may be known as “latching,” “sticking” or “stiction” and can cause the accelerator 306.1 to malfunction.

In more detail: in a configuration such as shown in FIGS. 4, 5A and 5B, the sense fingers 305/315, 305.1/315.1 are perpendicularly oriented to the alignment of the torsion beam 302, 302.1 facilitating the out-of-plane rotation of the movable member 301, 301.1 with respect to the stationary part 311/311.1 of the sense comb finger arrangement. In this type of sensor, the distance between the torsion beam 302/302.1 and the comb fingers 305/315, 305.1/315.1 tends to be comparatively large. One reason for the comparatively large distance is to have large inertia causing large out-of-plane restoring force. Here, “restoring force” means a force or forces to return the movable sense fingers 305/305.1 to a normal or non-accelerated position. Another reason relates to sensitivity of the accelerometer. The main weakness of the design is the possibility of sideways touching/pull-in of the sense finger combs 305/315, 305.1/315.1, especially in case of shock/vibration perpendicular to the overlapping sense comb fingers 305/315, 305.1/315.1. This touching/pull-in can cause reversible or non-reversible malfunction of the sensor. One possible way to improve the as-is configuration would be to choose a large gap for the overlap between the comb fingers and correctly placed structures (bumpstops) to prevent touching/pull-in from happening. But this approach to preventing the latching/pull-in behavior has drawbacks. The electrical sensitivity of the accelerometer is directly related the gap (the spaces 307/307.1) in the overlap region of the sense comb fingers. A larger gap reduces sensitivity of the accelerometer and therefore works against the requirement of an as-small-as-possible gap between the fingers. A solution is required.

### SUMMARY

To address the above-noted problems in the related art, embodiments disclosed herein can include a micro-electromechanical systems (MEMS) Z-axis accelerometer, comprising a substrate, a sensor configured to measure an acceleration along an axis that extends in a direction perpendicular to a plane of the substrate, and a spring axis configured to deform axially in response to the acceleration. The sensor can include a comb finger arrangement in which a comb finger overlap area is parallel with the spring axis. Fingers of the comb finger arrangement can extend in a non-sensing direction of a lowest restoring force. The comb finger arrangement can comprise first electrodes arranged in a first comb structure and second electrodes arranged in a second comb structure overlapped with the first comb structure. The second comb structure can be part of an effective proof mass configured to cause the second electrodes to be displaced in the direction perpendicular to the plane of the substrate in response to the acceleration. Horizontal parts of the first electrodes and the second electrodes can extend in a direction parallel to the spring axis.

### BRIEF DESCRIPTION OF THE DRAWINGS

FIG. 1A shows an accelerometer according to the present embodiments, in a state without displacement of the sense fingers in the X or Y directions.

FIG. 1B shows an accelerometer according to the present embodiments, in a state with displacement of the sense fingers in the X or Y directions.

FIG. 1C shows a cross-sectional view corresponding to dashed line 1C-1C in FIG. 1A.

FIG. 1D shows a cross-sectional view corresponding to dashed line 1D-1D in FIG. 1A.

FIG. 1E compares the vertical finger configuration with the horizontal finger configuration.

FIG. 1F shows a perspective view of the accelerometer according to the present embodiments.

FIG. 1G shows additional perspective views of the accelerometer according to the present embodiments.

FIG. 1H shows side views of the accelerometer according to the present embodiments.

FIG. 1I shows a plan view and another perspective view of the accelerometer according to the present embodiments.

FIGS. 2A and 2B show an accelerometer according to the related art.

FIGS. 3A and 3B show another accelerometer according to the related art.

FIG. 4 shows another accelerometer according to the related art.

FIGS. 5A and 5B show an accelerometer according to the related art, exhibiting unwanted touching or sticking of sense fingers.

### DETAILED DESCRIPTION

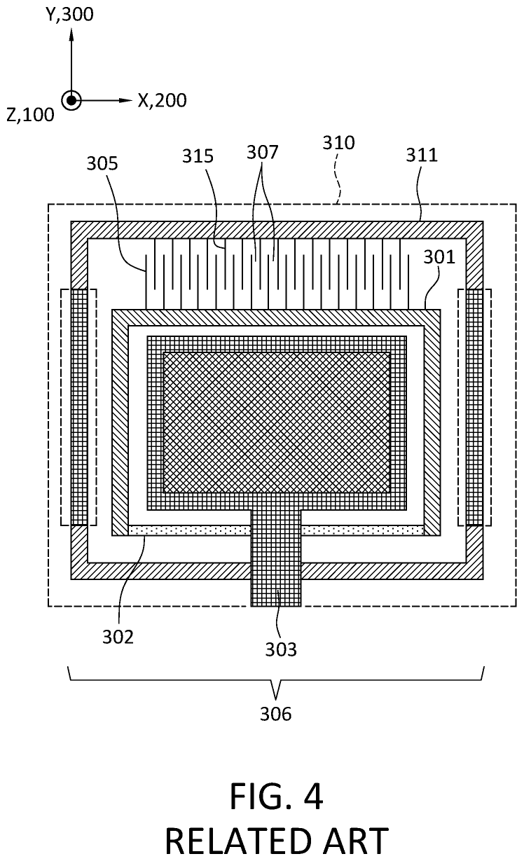

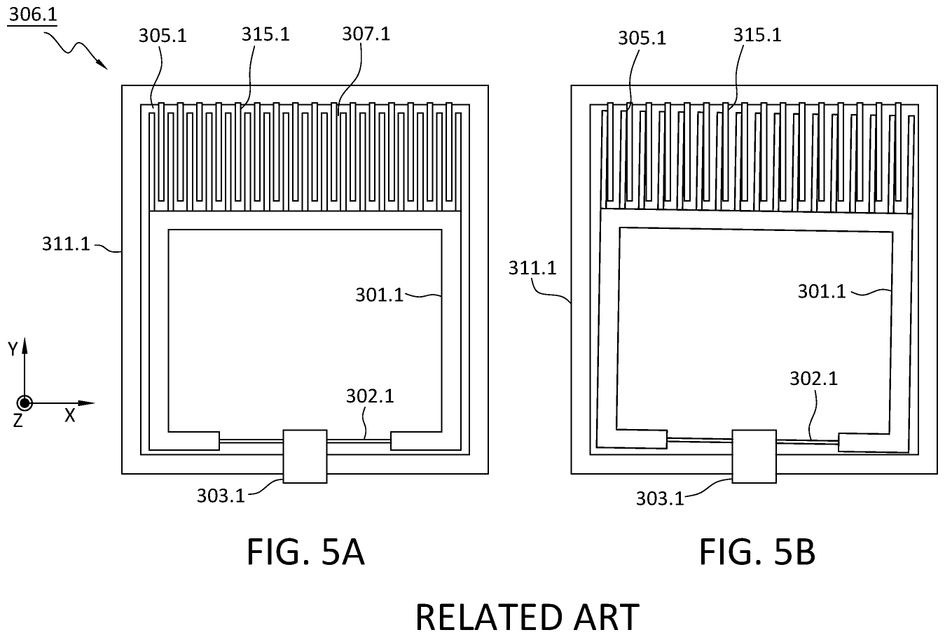

As described above, in the current state of the art (referring to FIG. 4), the sense comb fingers extend along the Y-axis from the inner beam structure 301 and the frame 311 (these structures may also be known as “rail structures”). When a high acceleration is input along the X-axis, the electrostatic force acting in the X direction on the left and right side of the spaces or gaps 307 between the sense fingers 305, 315 can get imbalanced because the movable fingers 305 are moved from their center position between the non-movable counterparts 315. As a consequence, sideways latching/pull-in (also, “stiction”) as illustrated in FIGS. 5A and 5B happens, causing a malfunction. In the worst case the stiction is non-reversible.

The restoring force applied by the torsion beam counteracts stiction, but as discussed above, the restoring force may be insufficient to prevent stiction altogether. The restoring force depends on multiple factors, including a mechanical spring constant of the torsion beam, the masses of the components of the accelerometer, and electrostatic forces that are proportional to surface areas of the sense fingers facing each other. The mechanical spring constant of the torsion beam may depend on specific designs and manufactures.

The forces applied by the torsion beam need to overcome forces applied by acceleration, so that the sense fingers can be returned to their normal or non-accelerated state after registering/measuring acceleration. In the related art, the force corresponding to the mechanical spring constant of the torsion beam/spring axis/torsional flexure 302 in the X direction tends to be an order of magnitude lower than the force corresponding to the mechanical spring constant in the Y-direction, which means that the mechanical restoring force that is applied by the torsion beam to pull the movable sense finger away from a static counterpart, in order to re-orient the accelerometer into a normal, non-accelerated state, is lower in the X direction. The worst-case electrostatic pull-in force in the X direction is also higher than in the Y direction because the fingers are oriented in the Y direction.

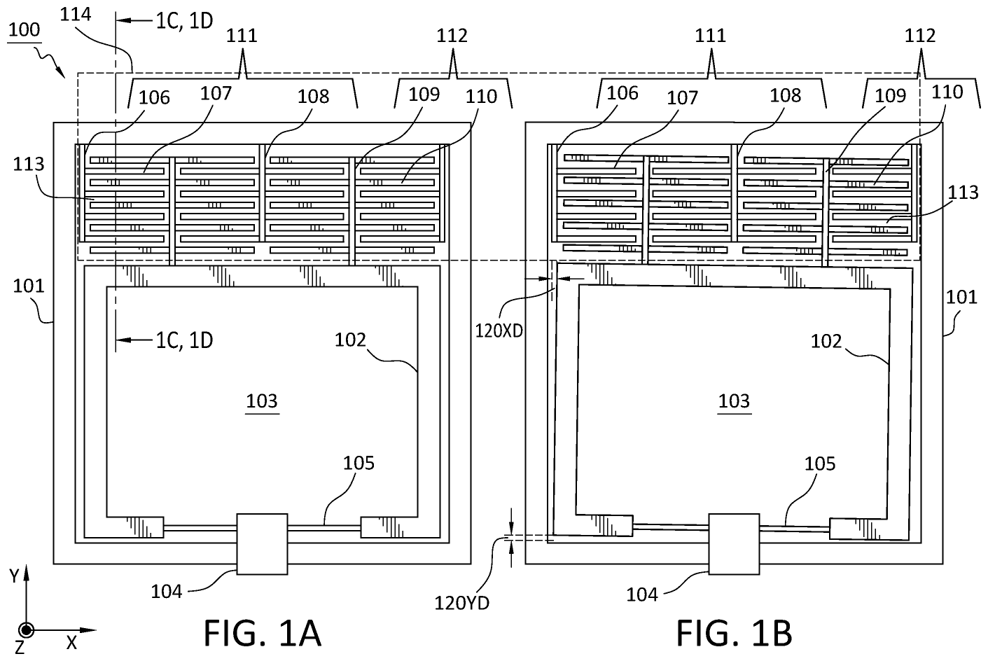

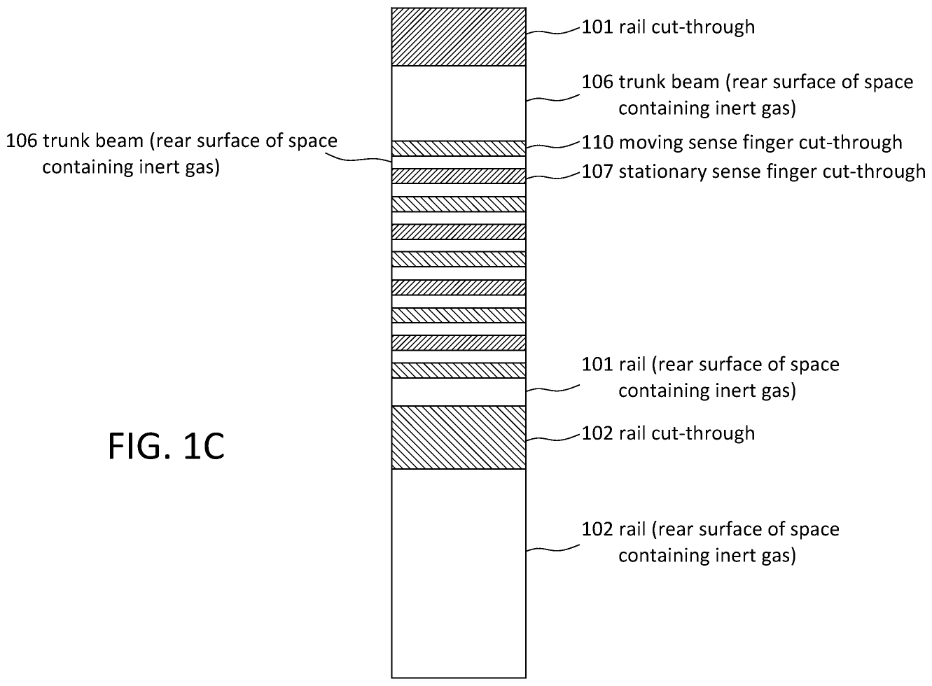

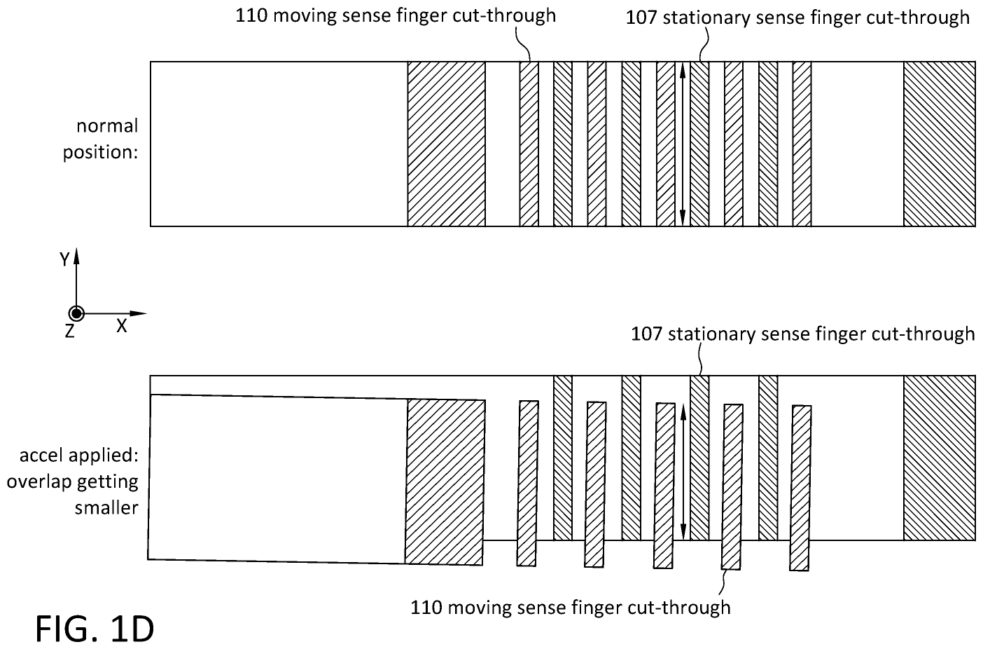

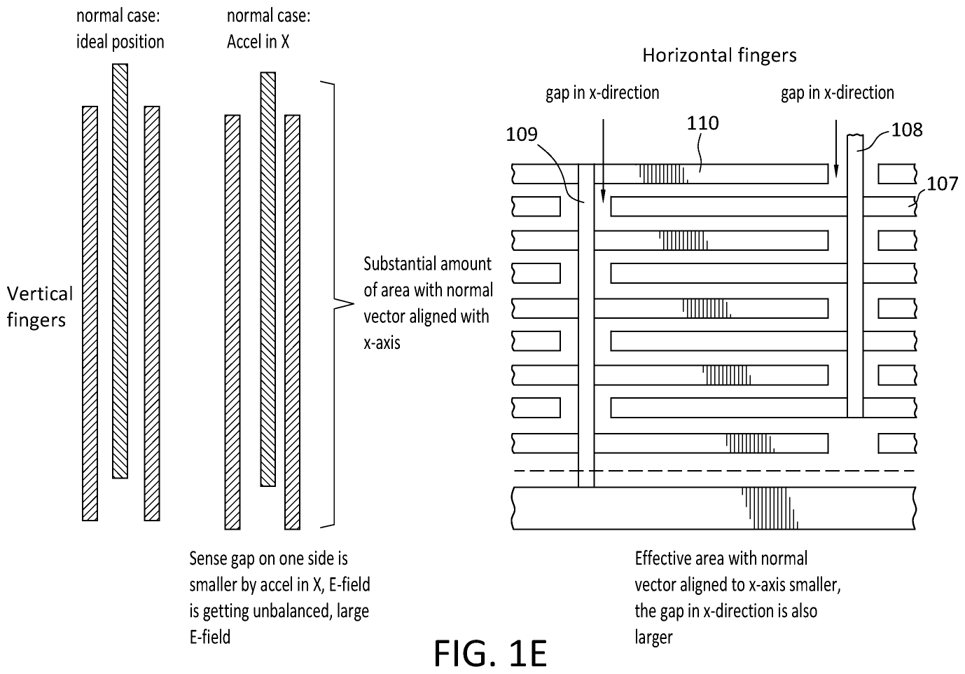

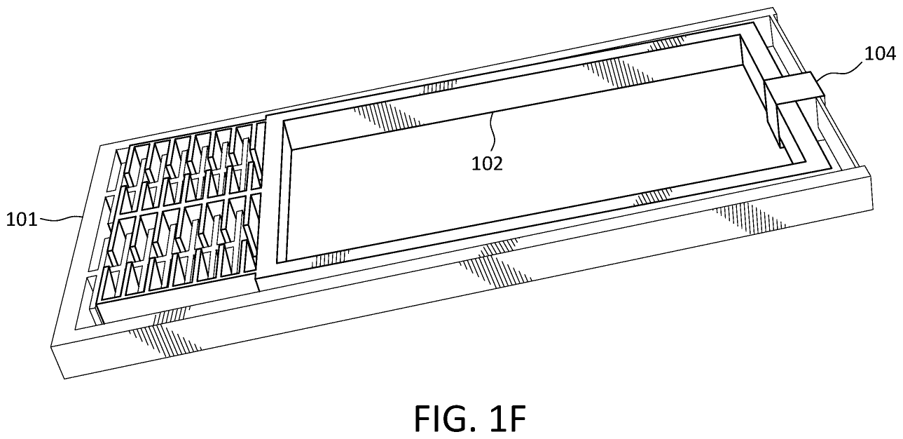

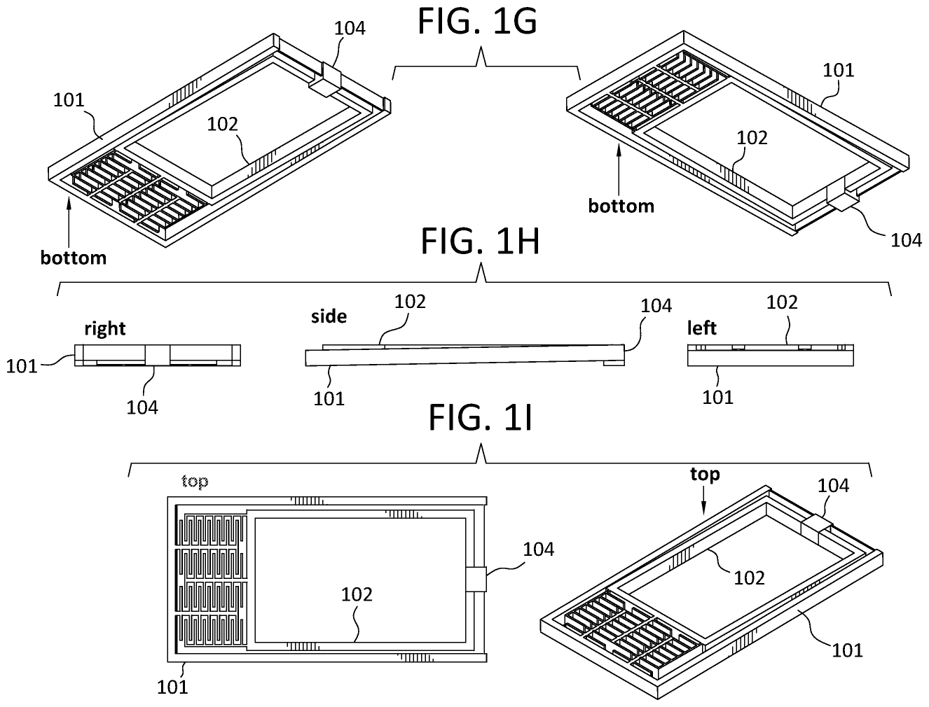

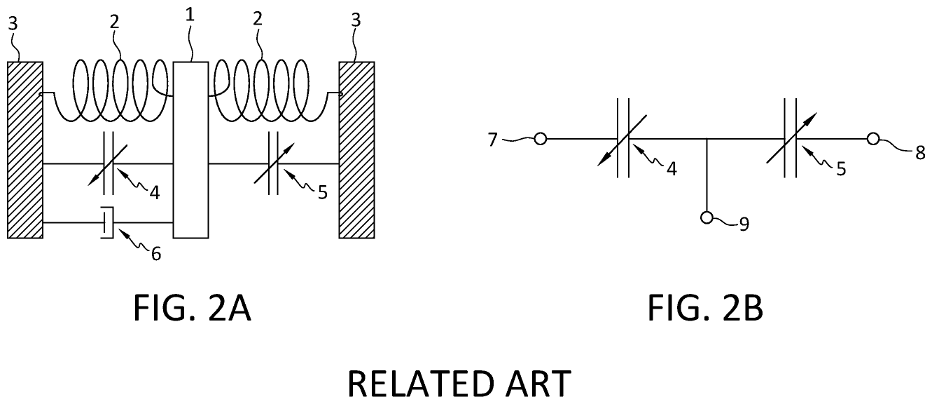

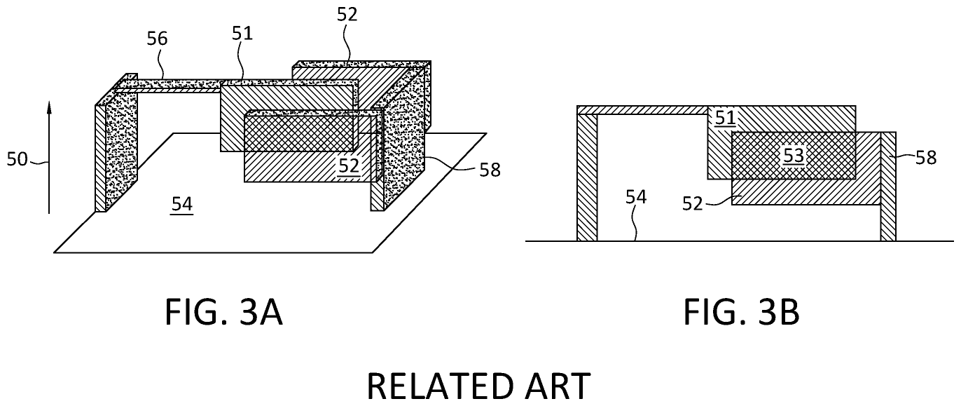

To solve the above-discussed problems, in the present embodiments the sense comb finger orientation is rotated by 90 degrees. As a result, referring now to FIGS. 1A and 1B, a sense comb finger overlap region 114 is now oriented parallel to the torsion beam 105. Because of this re-configuration, surface areas of sense fingers facing each other in the X direction are reduced, which reduces the electrostatic forces between the sense fingers that cause pull-in in the X direction. Moreover, gaps between structures of the sense fingers in the X direction can be increased, as compared to the vertical orientation, without sacrificing sensitivity. The increased gaps also reduce the electrostatic forces between the sense fingers that cause pull-in in the X direction. As a result, the load on the torsion beam is reduced and the restoring force is sufficient to prevent stiction.

Referring to FIG. 1A, in non-limiting embodiments according to the present disclosure, an accelerometer 100 can comprise a substrate 103. An outer beam structure or frame 101 and an inner beam structure 102 can be formed on the substrate 103. The frame 101 can be coupled in a substantially central lower portion thereof to a support structure 104. The inner beam structure 102 can be coupled to the support structure 104 by way of a torsion beam (also, “spring axis” or “torsional flexure”) 105. In non-limiting embodiments the dimensions of the frame 101 may be about 700 microns in the Y direction and about 500 microns in the X direction.

Like the related art devices discussed previously, the accelerometer 100 can be part of a MEMS accelerometer package that can include an Application Specific Integrated Circuit (ASIC). The accelerometer 100 can be wire bonded to the ASIC. The accelerometer 100 can be manufactured by known silicon manufacturing techniques including layering, doping, masking, etching, sintering and the like. The accelerometer 100 can be used in various useful applications, including for example in automotive vehicles and mobile phones.

The frame 101 can include or be coupled to electrodes 111. The inner beam structure 102 can include or be coupled to electrodes 112. The electrodes 111 and 112 can be in the form of fingers or interdigitated members, electrically coupled to each other, and arranged in a comb structure. More specifically, the electrodes 111 can include substantially vertical or vertically extending parts or members 106 and 108, coupled to or integrally formed with the frame 101. The vertical parts 106 and 108 may also be known in the art, and referred to herein, as “trunk beams.” Vertical part 108 can be in a substantially central position with respect to an upper part of the frame 101. Fingers 107, that is, substantially horizontal or horizontally extending parts or members 307, can project from the vertical parts 306 and 308 to form a comb structure.

The electrodes 112 can include substantially vertical parts or members 109, coupled to or integrally formed with the inner beam structure 102. Fingers 110, that is, substantially horizontal parts or members 110, can project from the vertical parts 109 to form a comb structure. The comb structures formed by the electrodes 111 and 112, respectively, can be overlapping or interdigitated, and electrically coupled to each other. Electrodes such as electrodes 111 and 112 may be known in the art, and may be referred to herein, as being or including “sense comb fingers.” Fingers 107 and 110, respectively, of the electrodes 111 and 112 can overlap each other in a sense comb finger overlap region 114, with spaces 113 existing between the fingers 107 and 110. The spaces 113 can be filled with an inert gas such as neon or argon.

The inner beam structure 102 and the structures coupled thereto, including horizontal sense fingers 110 and vertical parts or members 109, can be movable with respect to the frame 101. More specifically, due to forces, such as acceleration, being applied to the accelerometer 100, the torsion beam 105 can deform or torque axially in response to displacement of the inner beam structure 102 in the Z direction. Here, the inner beam structure 102 is part of the effective proof mass. The effective proof mass is a distributed structure comprising a proof mass and anything else coupled or attached to the proof mass that has the function or effect of causing a displacement in response to acceleration. Thus, the effective proof mass includes the inner beam structure 102 and the movable horizontal sense fingers 110 and vertical parts or members 109.

FIG. 1C shows a cross-sectional view corresponding to dashed line 1C-1C in FIG. 1A. FIG. 1C shows a cut-through view of the rail 101, the trunk beam 106 (the surface that would be visible, and corresponding to a space 113 filled with an inert gas), a cut-through view of the movable sense fingers 110, a cut-through view of the stationary sense fingers 107, a cut-through view of the rail (vertical part of inner beam structure) 102, and the surface of the rail 102 that would be visible in the view of FIG. 1C.

The displacement of the inner beam structure 102 in the Z direction can cause a change in the electrical coupling between electrodes 111 and 112, due to a change in overlapping area between the horizontal parts 107 and 110 of the electrodes 111 and 112. This is illustrated in the cross-sectional view of FIG. 1D. As shown in FIG. 1D, due to acceleration, the movable/moving sense fingers 110 can be displaced in the Z direction. As a result, the overlap between the movable sense fingers 110 and the stationary sense fingers 107 can change, and based on the change a measure of the acceleration can be obtained, similarly to the examples explained previously in the background discussion above.

Returning now to FIGS. 1A and 1B, FIG. 1A represents a state of the accelerometer 100 when there are no forces being applied to the accelerometer 100, or when there is no displacement in the X or Y direction and only displacement in the Z direction. FIG. 1B, on the other hand, represents a state of the accelerometer 100 when there is a force or forces being applied to the accelerometer 100 and there is displacement in the X and Y directions. Specifically, in FIG. 1B, due to the application of a force or forces which have a component acting parallel to the X direction in the representation of FIG. 1B, the inner beam structure 102 having the electrodes 112 including the moving horizontal sense fingers 110 and the vertical parts or members 109 is tilted or rotated to the right, with the respect to the frame 101 having the electrodes 111. This causes an angular displacement of the inner beam structure 102 and the structures coupled thereto to the right and upward on the left side of the inner beam structure 102. The angular displacement has an X-displacement amount 120XD. At the same time, a Y-displacement amount 120YD is introduced, due to the rotation and/or a force or forces which have a component acting parallel to Y direction.

In FIGS. 1A and 1B, it should be understood that the X and Y directions are “non-sensing” directions, because the accelerometer 100 is a Z-axis accelerometer configured specifically to sense acceleration in the Z direction. As described further on, the X direction is typically the non-sensing direction having applied thereto the lowest restoring force by the torsion beam 105. Here, “restoring force” refers to a force exerted by the torsion beam 105 to return the effective proof mass, including the inner beam structure 102 and the movable horizontal sense fingers 110 and vertical parts or members 109, to a non-displaced state relative to the frame 101. It is desirable to minimize the restoring force needed to return the inner beam structure 102 to the non-displaced state. By orienting the sense fingers horizontally, the required restoring force can be decreased as compared to the case with vertical sense fingers, as discussed in more detail in the following.

As discussed previously, to address the deficiencies in the related art, in the present embodiments the sense comb finger orientation is rotated by 90 degrees. The static comb fingers 107 are attached to a trunk beam 106 which is connected to the frame 101. The change in orientation of the sense fingers does not negatively impact their functioning as a variable capacitor. Because the surface area of respective horizontal fingers where the surface area has a normal vector aligned with the X axis is reduced, the electrostatic force along the X axis is reduced. Consequently, the restoring force applied by the torsion beam in the X direction need not be as strong as in the case of vertical sense fingers. Additionally, the gap in the X direction between the ends of the horizontal fingers and the trunk beams between electrodes is larger than the gap in the X direction between vertical sense fingers, reducing electrostatic forces in the X direction and also allowing a larger movement of the horizontal sense fingers. The larger movement enables the torsion beam to apply a higher mechanical restoring force in the X direction than in the case of vertical sense fingers. Latching/sticking along the X axis can be therefore prevented. Latching in the Y direction does not occur because the mechanical spring constant of the torsion beam 105 in most accelerometers tends to correspond to a restoring force that is about ten (10) times greater in the Y direction than in the X direction. Thus, the X direction is typically the non-sensing direction having applied thereto the lowest restoring force, as noted previously. Even with the same or narrower gaps between the overlapping fingers a reasonable mechanical restoring force preventing latching in the Y direction can be achieved.

The above is discussed in more detail below with reference to FIG. 1E. FIG. 1E compares aspects of the vertical sense finger configuration, that is, the related art, with the horizontal sense finger configuration of the present embodiments. The vertical sense finger configuration is shown on the left side of FIG. 1E. With acceleration in the X direction in the vertical sense finger configuration, the restoring force exerted by the torsion bar must overcome the effects of there being a substantial amount of surface area on respective surfaces of the vertical fingers facing each other. The facing surfaces generate E-field vectors normal to the facing surfaces and therefore aligned with the X axis. The gaps between the facing surfaces is made smaller by the acceleration in the X direction, causing large, unbalanced E-fields. The restoring force exerted by the torsion bar must overcome the effects of these E-fields in order to return the vertical sense fingers to their normal position.

The horizontal sense finger configuration is shown on the right side of FIG. 1E. With the horizontal sense finger configuration, the surface areas facing each other are smaller and the gap in the X direction between the surfaces is larger. These two factors reduce the force that the torsion bar must exert to return the sense fingers to a normal, unaccelerated position. Specifically, for example, only the ends of the stationary fingers 107 face the vertical parts 109, and the gap in the X direction between the stationary fingers 107 and the vertical parts 109 can be made larger than is the case with the gap in the X direction between the vertical sense fingers in the vertical sense finger configuration, without sacrificing sensitivity. Similarly, only the ends of the movable sense fingers 110 face the trunk beams 106, 108, and the gap in the X direction between the movable fingers 110 and the trunk beams 106, 108 can be made larger than is the case with the gap in the X direction between the vertical sense fingers in the vertical sense finger configuration, without sacrificing sensitivity.

FIGS. 1F, 1G, 1H and 1I show additional views of the accelerometer according to the present embodiments. FIG. 1F shows a perspective view of the accelerometer according to the present embodiments. FIG. 1G shows additional perspective views of the accelerometer according to the present embodiments. FIG. 1H shows side views of the accelerometer according to the present embodiments. FIG. 1I shows a plan view and another perspective view of the accelerometer according to the present embodiments.

The following comparison table summarizes several improvements in the present embodiments, as compared to the related art:

| | Vertical | Horizontal |
|---|---|---|
| | sense fingers | sense fingers |
| Mechanical restoring | modest | higher |
| force in X direction | | |
| Mechanical restoring | high | high |
| force in Y direction | | |
| Electrostatic force in X | high | low |
| direction | | |

The horizontal sense finger arrangement has better force balance characteristics than the vertical sense finger arrangement and is therefore a significant improvement over the state of the art.

It should be understood that the X, Y and Z directions as discussed above refer, for ease of understanding, to the X, Y and Z directions as commonly understood by well-established convention when viewed in the plane of the drawings. The accelerometer when in actual use in a physical environment might take on various orientations such that the X, Y and Z directions as described in the foregoing do not necessarily correspond to horizontal, vertical, in-out or front-to-back in the actual physical environment. For example, in actual use the accelerometer could be oriented such that the X direction is what would be called vertical in a given physical environment, or the Y direction is what would be called front-to-back or in-out in the given physical environment.

It will be apparent to the person having ordinary skill in the art that the manner of making and using the claimed invention has been adequately disclosed in the above-written description of the exemplary embodiments taken together with the drawings. Furthermore, the foregoing description of the embodiments according to the invention is provided for illustration only, and not for limiting the invention as defined by the appended claims and their equivalents.

It will be understood that the above description of the exemplary embodiments of the invention are susceptible to various modifications, changes and adaptations, and the same are intended to be comprehended within the meaning and range of equivalents of the appended claims.

What is claimed is:

1. A micro-electromechanical systems (MEMS) Z-axis accelerometer, comprising:
a substrate;
a sensor configured to measure an acceleration along an axis that extends in a direction perpendicular to a plane of the substrate; and
a spring axis configured to deform axially in response to the acceleration;
wherein the sensor includes a comb finger arrangement in which a comb finger overlap area is parallel with the spring axis.

2. The MEMS Z-axis accelerometer of claim 1, wherein fingers of the comb finger arrangement extend in a non-sensing direction of a lowest restoring force.

3. The MEMS Z-axis accelerometer of claim 1, wherein
the comb finger arrangement comprises:
first electrodes arranged in a first comb structure;
second electrodes arranged in a second comb structure overlapped with the first comb structure; and
the accelerator further comprises an effective proof mass configured to cause the second electrodes to be displaced in the direction perpendicular to the plane of the substrate in response to the acceleration;
wherein horizontal parts of the first electrodes and the second electrodes extend in a direction parallel to the spring axis.

4. The MEMS Z-axis accelerometer of claim 3, further comprising:
a frame supporting the first comb structure; and
an inner beam structure within the frame, the inner beam structure supporting the second comb structure;
wherein the inner beam structure is configured to act as part of the effective proof mass.

5. The MEMS Z-axis accelerometer of claim 4, wherein the first comb structure comprises, when the direction perpendicular to the plane of the substrate is a Z direction, a wall of the frame extends in a Y direction perpendicular to the Z direction, and the spring axis extends in an X direction perpendicular to the Y direction and the Z direction:
a plurality of first vertical parts extending in the Y direction and being supported by the frame; and
a plurality of first horizontal parts supported by respective ones of the first vertical parts, the first horizontal parts extending in the X direction.

6. The MEMS Z-axis accelerometer of claim 5, wherein the second comb structure comprises:
a plurality of second vertical parts extending in the Y direction and being supported by the inner beam structure; and
a plurality of second horizontal parts supported by respective ones of the second vertical parts, the second horizontal parts extending in the X direction;
wherein the second horizontal parts overlap the first horizontal parts, and are separated by spaces from the first horizontal parts.

7. The MEMS Z-axis accelerometer of claim 6, further comprising:
a support structure;
wherein the frame is coupled in a substantially central lower portion thereof to the support structure; and
the inner beam structure is coupled to the support structure by way of the spring axis (105).

8. A MEMS Z-axis accelerometer, comprising:
first electrodes arranged in a first comb structure;
second electrodes arranged in a second comb structure overlapped with the first comb structure;
an effective proof mass configured to cause the second electrodes to be displaced in a Z direction in response to a force applied to the accelerometer; and
a torsion beam coupled to the effective proof mass, the torsion beam extending in an X direction and being configured to torque axially in response to displacement of the effective proof mass in the Z direction;
wherein horizontal parts of the first electrodes and the second electrodes extend in the X direction.

9. The MEMS Z-axis accelerometer of claim 8, further comprising:
a frame supporting the first comb structure; and
an inner beam structure supporting the second comb structure;
wherein the inner beam structure is configured to function as part of the effective proof mass.

10. The MEMS Z-axis accelerometer of claim 9, further comprising:
a support structure configured to support the torsion beam.

11. The MEMS Z-axis accelerometer of claim 10, wherein the support structure is located in a substantially central part of a lower wall of the frame.

12. The MEMS Z-axis accelerometer of claim 11, wherein the torsion beam is coupled between the support structure and the inner beam structure.

13. The MEMS Z-axis accelerometer of claim 9, wherein the first comb structure includes first vertical parts extending in the Y direction from an upper wall of the frame, the horizontal parts of the first electrodes extending from the first vertical parts.

14. The MEMS Z-axis accelerometer of claim 13, wherein the second comb structure includes second vertical parts extending in the Y direction from an upper wall of the inner beam structure, the horizontal parts of the second electrodes extending from the second vertical parts.

15. A MEMS Z-axis accelerometer, comprising:
overlapping sense comb structures; and
a torsional flexure coupled to one of the sense comb structures;
wherein comb fingers of the sense comb structures extend in a same direction as the torsional flexure.

16. The MEMS Z-axis accelerometer of claim 15, further comprising:
a frame supporting one of the overlapping sense comb structures; and
an inner beam structure inside the frame and supporting another of the overlapping sense comb structures.

17. The MEMS Z-axis accelerometer of claim 16, further comprising:
a support structure;
wherein the torsional flexure is coupled between the support structure and the inner beam structure.

18. The MEMS Z-axis accelerometer of claim 16, wherein the comb fingers extend from vertical parts of the sense comb structures, the vertical parts extending in a direction orthogonal to the direction of the torsional flexure.

19. The MEMS Z-axis accelerometer of claim 18, wherein first ones of the vertical parts of the sense comb structures extend from an upper wall of the frame.

20. The MEMS Z-axis accelerometer of claim 18, wherein second ones of the vertical parts of the sense comb structures extend from an upper wall of the inner beam structure.
